(19) United States
(12) Patent Application Publication
(10) Pub. No.: US 2018/0315630 A1
(43) Pub. Date: Nov. 1, 2018

(54) Charge Metrology for Integrated Measurement

(71) Applicant: SEMILAB Semiconductor Physics Laboratory Co., Ltd., Budapest (HU)

(72) Inventors: Dmitriy Marinskiy, Tampa, FL (US); Andrew Findlay, Tampa, FL (US); Bret Schrayer, Tampa, FL (US); Jacek Lagowski, Tampa, FL (US); Piotr Edelman, Tampa, FL (US); Alexandre Savtchouk, Tampa, FL (US)

(21) Appl. No.: 15/967,933

(22) Filed: May 1, 2018

Related U.S. Application Data
(60) Provisional application No. 62/492,894, filed on May 1, 2017.

(51) Int. Cl. H01L 21/67; H01L 21/66

(52) U.S. Cl. CPC H01L 21/67242; H01L 22/14; H01L 21/67196; H01L 21/67069; H01L 21/67051

(57) ABSTRACT

A method for measuring charging of a semiconductor wafer associated with processing the semiconductor wafer includes using a probe assembly at a charge monitoring module to measure a charge on the semiconductor wafer prior to processing the semiconductor wafer using a processing tool, the probe assembly being located proximate to a processing station of the processing tool; transferring the semiconductor wafer from the charge monitoring module to the processing station using an automated wafer handling apparatus; processing the semiconductor wafer at the processing station using the processing tool; transferring the processed wafer from the processing station back to the charge monitoring module; using the probe assembly at the charge monitoring module to measure a charge on the semiconductor wafer after processing the wafer; and analyzing the measured charge on the semiconductor wafer both before and after processing the semiconductor wafer to determine information about charging of the wafer due to processing the semiconductor wafer using the processing tool.

### CROSS-REFERENCE TO RELATED APPLICATIONS

This application claims priority to Provisional Application No. 62/492,894, entitled “CHARGE METROLOGY FOR INTEGRATED MEASUREMENT,” filed on May 1, 2017, the entire contents of which are incorporated herein by reference.

### BACKGROUND

Charging of wafers during the semiconductor device manufacturing process is a significant factor in yield loss. This problem is increasingly important for most advanced 10 nm and sub-10 nm technology nodes which often involve forming increasingly thin dielectric layers. Wafer charging inherently occurs during wafer processing in certain tools indispensable in manufacturing sequence, such as plasma etching tools and modern single wafer wet cleaning tools. Wafer charging in plasma processing (e.g., dry etch) originates, for example from unbalanced currents of negative and positive species. Charging damage in wet cleaning tools can originate from interaction with charges already present on an incoming wafer (e.g., induced by previous processing, such as plasma etch). In wet cleaning, a cleaning liquid flow (e.g., DI water) can induce electrostatic charge-buildup on wafer surface due to advection of charge by the flow of the liquid dispensed from the nozzle on the spinning wafer. Charging of the wafer can also be caused by nitrogen drying or by inductive charging from plastic materials surrounding the wafer in a processing chamber.

There are multiple ways that charging can affect wafer yield. These include (a) a shift in device performance characteristics due to charging, (b) increased density of particulates on the surface due to charging, and (c) localized electrostatic discharge due to charging creating defects destructive to device performance. Consequently, charging may become a yield limiting issue for advanced semiconductor manufacturing and reducing (e.g., minimizing) the wafer charge is of paramount importance. This may involve optimizing the processing tools hardware, the operation conditions, and/or the chemicals used. It may also involve incorporation of discharging elements and steps in processing sequence.

### SUMMARY

A goal of the disclosed technology is facilitating wafer charging control during the actual wafer processing. Toward that goal, the present disclosure introduces charge metrology for integrated charge measurement with a wafer charge measuring module incorporated in a processing tool (e.g., a wafer cleaning tool or an etch tool). Integrated charge measurement can provide rapid wafer inspection before, during, and/or after processing steps with immediate feedback for charging evaluation and control.

In one aspect, the invention features a method for measuring charging of a semiconductor wafer associated with processing the semiconductor wafer. The method includes using a probe assembly at a charge monitoring module to measure a charge on the semiconductor wafer prior to processing the semiconductor wafer using a processing tool, the probe assembly being located proximate to a processing station of the processing tool (e.g., housed in the same housing as the processing station or accessible by wafer handling apparatus of the processing tool); transferring the semiconductor wafer from the charge monitoring module to the processing station using an automated wafer handling apparatus; processing the semiconductor wafer at the processing station using the processing tool; transferring the processed wafer from the processing station back to the charge monitoring module; using the probe assembly at the charge monitoring module to measure a charge on the semiconductor wafer after processing the wafer; and analyzing the measured charge on the semiconductor wafer both before and after processing the semiconductor wafer to determine information about charging of the wafer due to processing the semiconductor wafer using the processing tool.

Implementations of the method can include one or more of the following features. For example, analyzing the measured charge on the semiconductor wafer both before and after processing the semiconductor wafer can further provide information about charging of the semiconductor wafer due to processing the wafer using the processing tool.

Analyzing the measured charge on the semiconductor wafer can further provide information about pre-processing charge on the semiconductor wafer.

Analyzing the measured charge on the semiconductor wafer can further provide information about post-processing charge on the semiconductor wafer.

Processing the semiconductor wafer comprises cleaning a surface of the semiconductor wafer. In some embodiments, processing the semiconductor wafer includes etching a layer of a material on the semiconductor wafer.

A top layer of the semiconductor wafer can be a layer of a dielectric material and the analyzing the measured charge comprises determining information about a charge on the layer of the dielectric material. The layer of dielectric material can have a thickness of about 100 Angstroms or less.

The probe assembly can include one or more non-contact probes. The non-contact probes can be configured to provide surface voltage measurements indicative of a charge on the wafer. The non-contact probes can include a Kelvin probe or a Monroe probe. Using the probe assembly at the charge monitoring module to measure a charge on the semiconductor wafer can include positioning the wafer proximate to the one or more non-contact probes and causing relative motion between the semiconductor wafer and the one or more non-contact probes. Analyzing the measured charge can include mapping a distribution of charge on the semiconductor wafer based on measurements made while causing the relative motion between the semiconductor wafer and the probe assembly. The method can include identifying a charging pattern attributable to the processing tool based on the mapped charge distribution. In some embodiments, the method includes making adjustments to the processing tool or to a processing step based on the charging pattern.

The probe assembly can include multiple non-contact probes and a surface voltage readout for each probe in the probe assembly is calibrated using surface voltage data measured by each probe at one or more common positons relative to the semiconductor wafer.

The semiconductor wafer can include at least one patterned layer corresponding to integrated circuit structures during the processing.

The charge monitoring module can include a chamber housing the probe assembly that provides environmental separation of the probe assembly from a processing environment associated with the processing station.

Among other advantages, the disclosed technology can allow for accurate charge measurement of semiconductor wafers before, during, and/or immediately after processing of the wafer. For example, embodiments feature charge monitoring modules integrated with a processing tool that enable charge measurements to be made with little delay after processing the wafer (e.g., within minutes or even seconds of processing). Accordingly, charge dissipation that occurs over longer time periods (e.g., tens of minutes to hours), that may lead to less accurate measurements, may be avoided or reduced.

Moreover, the disclosed technology can allow for characterization and reduction of charging associated with a process tool. For example, by accurately mapping charge accumulation on a wafer due to a wafer processing step, the processing tool can be recalibrated or otherwise adjusted to reduce the mapped charge accumulation.

Furthermore, the disclosed technologies can improve wafer yield. For example, by reducing undesirable wafer charging associated with wafer processing that can reduce wafer yields, the disclosed technologies can increase yields.

### BRIEF DESCRIPTION OF THE DRAWINGS

FIG. 1 is a schematic diagram showing a conventional arrangement of a separate charge inspection equipment used for wafer metrology in conjunction with other processing equipment

FIG. 2 shows a schematic diagram showing processing equipment with an integrated charge monitoring module.

FIG. 3 shows a schematic diagram illustrating an embodiment of processing equipment with an integrated charge monitoring module.

FIG. 4 is a schematic diagram of an embodiment of a processing system that includes a charge measuring module.

FIG. 5 is a schematic diagram of another embodiment of a processing system that includes a charge measuring module.

FIG. 6 is a perspective view of a wafer cleaning system that includes a charge measuring module.

### DETAILED DESCRIPTION

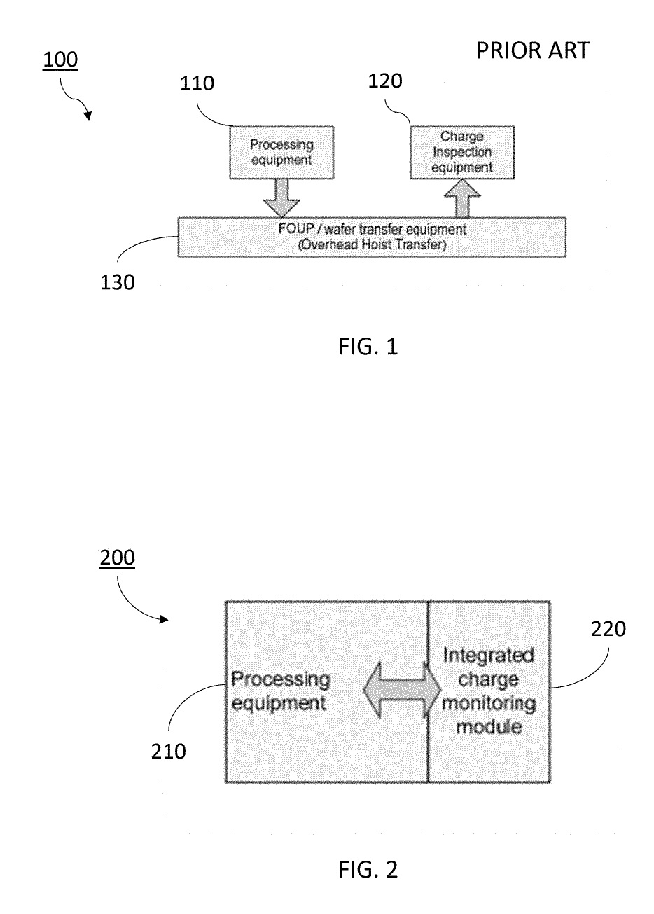

Conventionally, the measurement of charge on a wafer is done in a metrology tool separated from the processing tool. Referring to FIG. 1, this is illustrated by a system 100 that includes processing equipment 110 (e.g., an etching tool or a wafer cleaning tool) that is separate from charge inspection equipment 120. Wafer transfer equipment 130 (e.g., involving an overhead hoist transfer and/or a Front Opening Unified Pod (FOUP)) is used to move wafers between processing equipment 110 and charge inspection equipment 120.

These low throughput measurements are generally considered too slow for “in line” testing. They typically involve removing a wafer from processing tool 110, transferring the wafer to the metrology tool (charge inspection equipment 120) in a separate location, placing the wafer in the metrology tool and making a charge measurement of the wafer. In addition to significant time delay, all these steps can produce charge dissipation and/or neutralization which interferes with determining the actual charging caused by processing.

According to the present disclosure, wafer charge measurement is done inside the processing tool, without the wafer leaving the tool. Referring to FIG. 2, this is illustrated by a system 200 composed of processing equipment 210 that is integrated with a charge monitoring module 220.

Rapid charge measurement of wafers is achieved using charge monitoring module 220 which includes, e.g., an array of vibrating surface voltage probes above the wafer. The module includes actuators which move the wafer and probe array relative to one another, enabling high speed wafer mapping without sacrifice in measurement precision. Close/open separation between integrated measurement module and the chamber in processing tool can provide ambient separation that is important considering hazardous or corrosive nature of liquids used in wet wafer cleaning.

The integrated measurement enables sequential wafer charging inspection for multiple steps used in wafer cleaning. Measurement before and after processing provides a means for verification and optimization of steps causing wafer charging and also steps causing charge removal.

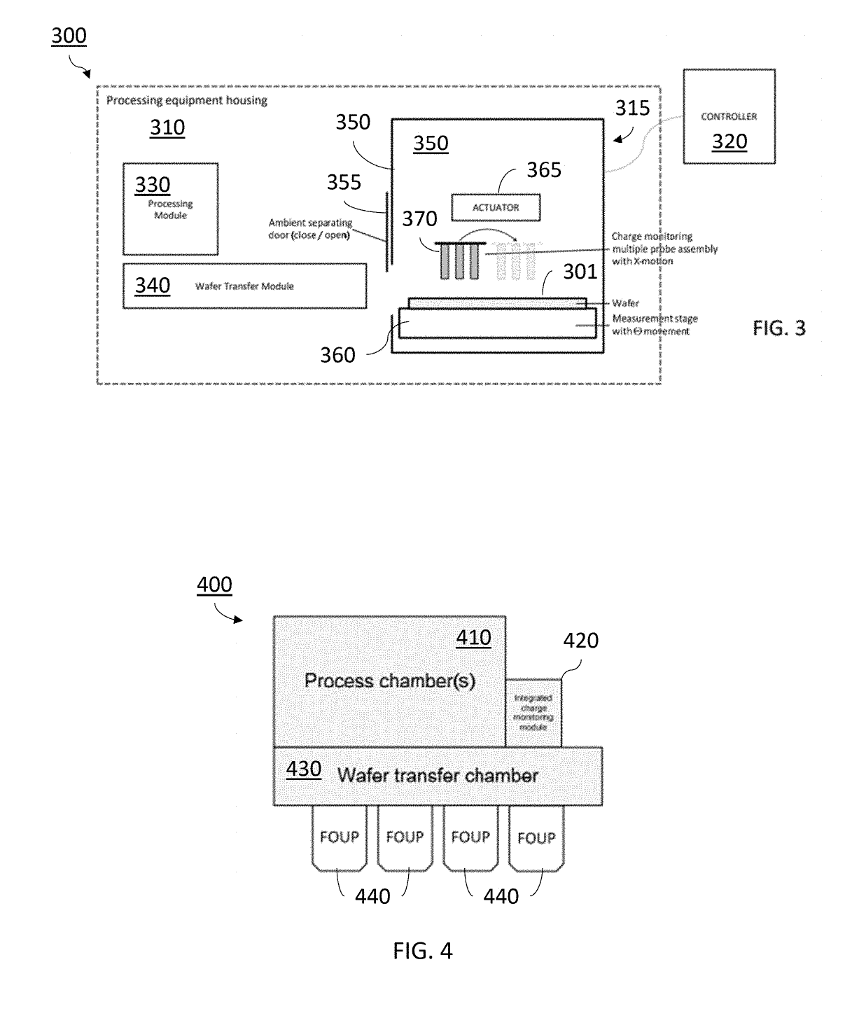

FIG. 3 shows a schematic diagram illustrating an embodiment of a wafer processing system 300 that includes a wafer processing module 330, a wafer transfer module 340, and a charge monitoring module 315 that are contained within a processing equipment housing 310. System 300 also includes a controller 320 for controlling the charge monitoring module. While controller 320 is illustrated in FIG. 3 and being separated from housing 310, more generally, the controller can be integrated with the housing or separate.

Charge monitoring module 315 includes a housing 350, a wafer stage 360, and a probe assembly 370. Also included are one or more actuators 365 for causing relative motion between probe assembly 370 and wafer 301 (on the stage). For example, probe assembly 370 can be attached to an actuator 365 which translates (e.g., linearly, in one or more dimensions) the probe assembly, while wafer stage 360 spins the wafer.

Probe assembly 365 includes two or more non-contact probes (e.g., Kelvin probes or Monroe probes, often referred to as CPD probes, i.e. Contact Potential Difference probes). Such probes typically make measurements of the contact potential difference voltage between the probe electrode and the wafer surface. Knowing the electrode contact potential, this value gives the surface voltage value, V, which is used as a measure of surface charge density, Q, on a dielectric layer since Q=V·C, where C is the capacitance of the dielectric layer. In some embodiments, the assembly includes three probes spaced apart (e.g., along a common direction) so that one probe measures charge characteristics close to the edge of the wafer, one measures charge characteristics at the center of the wafer, while the third probe measured charge characteristics at some intermediate radial position between the edge and the center. Spinning the wafer relative to such a probe assembly can enable rapid evaluation of substantially the entire wafer.

Examples of techniques for measuring charge distributions of wafer using non-contact probes are disclosed the following publications: Findlay, A. D., Marinskiy, D., Edelman, P., Wilson, M., Savtchouk, A., Almeida, C., & Lagowski, J. “Non-Visual Defect Monitoring with Surface Photovoltage Mapping,” ECS Transactions, 75(4), 13-27 (2016); K. Nauka, J. Lagowski, and P. Edelman, “Surface Photovoltage and Contact Potential Difference Imaging of Defects Induced by Plasma Processing of IC Devices,” A. R. Mickelson, Editor, Proceedings of the Sixth International Conference held in Boulder, Colo., 3-6 Dec. 1995, Vol. 149, p. 281, Institute of Physics Publishing (1996); and D. K. Schroder, “Semiconductor Materials and Device Characterization,” Chapter 9.4, (Wiley-Interscience, New Jersey, 2006) the entire contents each of which are incorporated herein by reference.

In some embodiments, surface voltage readouts for each probe in the probe assembly are used to calibrate the probe assembly by comparing surface voltage data measured by each probe at one or more common positons on the semiconductor wafer. Similar techniques are described by Marinskiy, D., Lagowski, J., Wilson, M., Findlay, A., Almeida, C., & Edelman, P. in “New approach to surface voltage based non-visual defect inspection,” ECS Transactions,60(1), 917-922 (2014).

Module housing 350 provides a chamber 351 in which the charge measurements are conducted. Housing 350 also includes an entry/exit port 355 such that chamber 351 may be sealed from the environment of processing module 330. This can allow the charging measurements to be provided at different temperatures and/or different pressures and/or with different atmospheres from the wafer processing. Chamber 351 can be purged with a purge gas (e.g., nitrogen or air) when each new wafer is introduced for measurement. This can also protect components of the module (e.g., the probes) from possibly harmful chemicals used in the wafer processing. For instance, where acidic materials are used to clean the wafer, the closed housing can reduce exposure of the probes to the acid.

Controller 320 (e.g., a computer controller) is in communication with other components of charge monitoring module 315 to coordinate their operation and process probe data. Generally, the controller is in communication with the other components via cabling or via a wireless connection. Controller 320 can be integrated (e.g., via hardware and/or software integration) with the controller that controls operation of the processing equipment.

Processing system 300 includes at least one processing module 330. For example, where the processing equipment is a wafer cleaning station, the equipment includes at least one cleaning module. In some embodiments, processing system 300 includes multiple processing modules each capable of processing a corresponding wafer in parallel to the other processing modules.

Wafer transfer module 340 includes one or more actuation systems (e.g., robotic arms) for moving wafers between the processing modules and the monitoring module.

In some embodiments, processing station 300 is a wafer cleaning station and the integrated charge monitoring module is used to map charge on a semiconductor wafer before, during, and after cleaning the wafer. The charge measurements are then analyzed (e.g., using controller 320) to determine information about charging and/or discharging of the wafer due to processing the semiconductor wafer using the processing tool. The measurements can also be used to determine information about pre-processing charge and/or post-processing charge on the semiconductor wafer.

Analyzing the measured charge, in some embodiments, includes mapping a distribution of charge on the semiconductor wafer based on charge measurements made while moving the semiconductor wafer and the probe assembly relative to each other and making a sequence of measurements at different positions across on the wafer's surface. A charge distribution map generated this way can be used to identify a charging pattern attributable to the processing tool based on the mapped charge distribution. For example, models of wafer charging can be used to correlate the mapped charge distribution to processing parameters. See, e.g., Mui, D. S., Lenz, E. H., Cyterski, C., Venkataraman, K., & Kawaguchi, M. “Wafer Surface Charging Model for Single-Wafer Wet-Spin Processes,” IEEE Transactions on Semiconductor Manufacturing, 24(4), 552-558 (2011), the entire contents of which is incorporated herein by reference.

The processing tool can be adjusted based on the charging pattern to reduce undesirable charging effects. For example, the various parameters of the processing tool that affect charging can be adjusted based on the charging pattern. These can include, for example, materials used in operation of the processing tool (see, e.g., Wada, M., Sueto, T., Takahashi, H., Hayashi, N., & Eitoku, A., “Study of static electricity in wafer cleaning process,” Solid State Phenomena (Vol. 134, pp. 263-266), Trans Tech Publications (2008), showing that plastic materials used in cleaning equipment can produce electrostatic charge), design of the processing tool (see, e.g., J. Lagowski, A. Hoff, L. Jastrzebski, P. Edelman, and T. Esry, Mat. Res. Soc. Symp., 428, 437 (1996), discussing effects of plasma system design (clamping, Triode electrode, magnetic enhancement on wafer charging), change in resistivity of spraying solution, and wet processing time and speed (see, e.g., Mui, D. S., Lenz, E. H., Cyterski, C., Venkataraman, K., & Kawaguchi, M.,“Wafer Surface Charging Model for Single-Wafer Wet-Spin Processes,” IEEE Transactions on Semiconductor Manufacturing, 24(4), 552-558 (2011)). The entire contents of these publications is incorporated herein by reference.

Similar techniques can be adopted for other processing steps in which understanding and controlling wafer charging and/or discharging are important to wafer yields.

In general, charge monitoring can be performed at a variety of different phases during wafer processing. For example, in modern integrated circuit manufacturing, there may be 20 to 30 or more different process steps. With each successive step or sequence of steps, the components of the integrated circuit become increasingly complex and the value of the wafer increases. Accordingly, charge monitoring of a wafer after the formation of one or more patterned layers on the underlying semiconductor substrate becomes increasingly important to maintain yields. In some embodiments, charge monitoring is performed using an integrated charge monitoring module at stages where the wafer includes one or more patterned layers. In some cases, charge monitoring is performed on a dielectric layer (e.g., SiO₂ or a high k dielectric, like HfO₂ or a ZAZ material). The dielectric layers may be extremely thin, such as 100 Angstroms or less (e.g., 80 Angstroms or less, 60 Angstroms or less, 50 Angstroms or less, 40 Angstroms or less, 30 Angstroms or less, 20 Angstroms or less, 10 Angstroms or less).

Charge on an extremely thin dielectric layer and/or on a patterned layer with extremely small critical dimensions (e.g., 40 nm or less, 30 nm or less, 20 nm or less, 10 nm or less) can dissipate on time scales that are on the order of minutes or less (e.g., 5 minutes or less, 3 minutes or less, 1 minute or less). Accordingly, it may be particularly important to perform charge measurements within those time scales in order to accurately map the charge on such wafers.

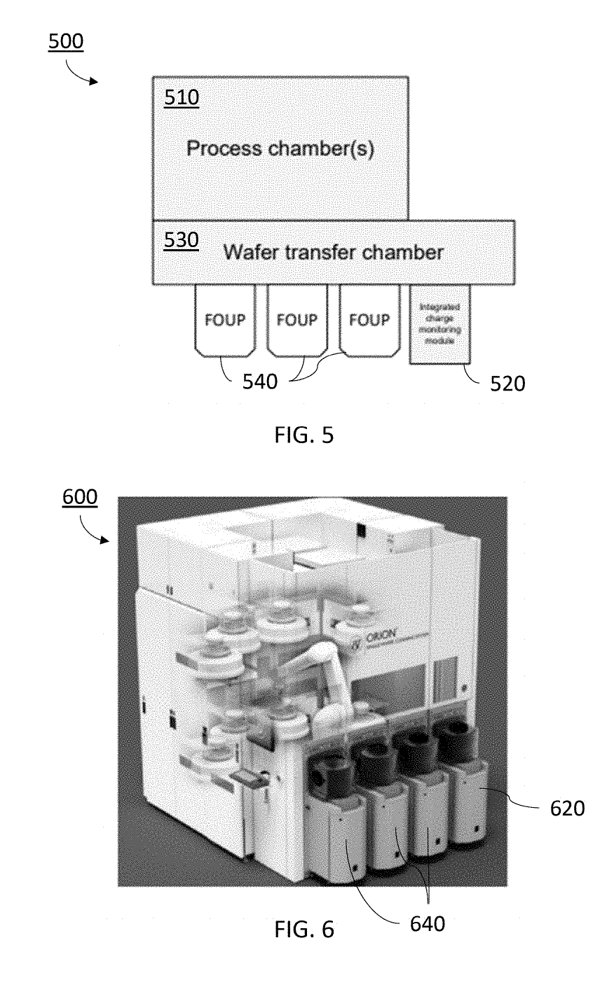

Referring to FIGS. 4 and 5, charge monitoring modules can be integrated with a processing tool in a variety of ways. For instance, referring to FIG. 4, in some embodiments, a processing system 400 includes a charge monitoring module 420 integrated or attached to a process chamber 410 of the processing system, which also includes a wafer transfer chamber 430 that facilitates wafer transfer between the process chamber(s) and charge monitoring module 420, and between the chamber(s), module 420, and four FOUPs 440.

Alternatively, referring to FIG. 5, in some embodiments, a wafer processing system 500 includes a charge monitoring module 520 integrated with a wafer transfer chamber 530, which is responsible for transferring wafers to and from FOUPs 540 or other carriers and process chamber(s) 510.

Wafer charge evaluation using the charge monitoring modules can be implemented once or multiple times during wafer processing using the wafer processing equipment. For example, charge metrology can be performed initially before processing begins. Alternatively, or additionally, processing can be done after processing is completed but before the wafer is removed from the processing equipment. Charge metrology can also be performed between different process steps in equipment that performs multiple processing steps.

Various possible wafer transfer sequence examples are as follows:
A) FOUP—charge monitoring module—process chamber—charge monitoring module—FOUP.
B) FOUP—charge monitoring module—process chamber—FOUP.
C) FOUP—process chamber—charge monitoring module—FOUP.
D) FOUP—charge monitoring module—first process chamber—charge monitoring module—second process chamber—charge monitoring module—FOUP.

In some implementations, a charge monitoring module can be integrated with commercially-available wafer processing systems. FIG. 6 shows an example of a commercially-available wafer cleaning system 600, the Orion wafer cleaning system from Tokyo Electron, into which a charge monitoring module 620 is integrated. Specifically, wafer cleaning system 600 has four FOUP ports. Three of these ports are occupied by a FOUP 640, while the fourth is occupied by a charge monitoring module 620, which is configured in the same form factor as FOUPs 640. In general, charge monitoring modules can be integrated into other commercially-available wafer cleaning tools, such as other systems from Tokyo Electron (e.g., the Cellesta-i system) or Lam Research (e.g., EOS, Gamma, and Corona systems).

Various embodiments are described. Other embodiments are in the following claims.

What is claimed is:

1. A method for measuring charging of a semiconductor wafer associated with processing the semiconductor wafer, the method comprising:
using a probe assembly at a charge monitoring module to measure a charge on the semiconductor wafer prior to processing the semiconductor wafer using a processing tool, the probe assembly being located proximate to a processing station of the processing tool;
transferring the semiconductor wafer from the charge monitoring module to the processing station using an automated wafer handling apparatus;
processing the semiconductor wafer at the processing station using the processing tool;
transferring the processed wafer from the processing station back to the charge monitoring module;
using the probe assembly at the charge monitoring module to measure a charge on the semiconductor wafer after processing the wafer; and
analyzing the measured charge on the semiconductor wafer both before and after processing the semiconductor wafer to determine information about charging of the wafer due to processing the semiconductor wafer using the processing tool.

2. The method of claim 1, wherein analyzing the measured charge on the semiconductor wafer both before and after processing the semiconductor wafer further provides information about charging of the semiconductor wafer due to processing the wafer using the processing tool.

3. The method of claim 1, wherein analyzing the measured charge on the semiconductor wafer further provides information about pre-processing charge on the semiconductor wafer.

4. The method of claim 1, wherein analyzing the measured charge on the semiconductor wafer further provides information about post-processing charge on the semiconductor wafer.

5. The method of claim 1, wherein processing the semiconductor wafer comprises cleaning a surface of the semiconductor wafer.

6. The method of claim 1, wherein processing the semiconductor wafer comprises etching a layer of a material on the semiconductor wafer.

7. The method of claim 1, wherein a top layer of the semiconductor wafer is a layer of a dielectric material and the analyzing the measured charge comprises determining information about a charge on the layer of the dielectric material.

8. The method of claim 7, wherein the layer of dielectric material has a thickness of about 100 Angstroms or less.

9. The method of claim 1, wherein the probe assembly comprises one or more non-contact probes.

10. The method of claim 9, wherein the non-contact probes are configured to provide surface voltage measurements indicative of a charge on the wafer.

11. The method of claim 9, wherein the non-contact probes comprise a Kelvin probe or a Monroe probe.

12. The method of claim 9, wherein using the probe assembly at the charge monitoring module to measure a charge on the semiconductor wafer comprises positioning the wafer proximate to the one or more non-contact probes and causing relative motion between the semiconductor wafer and the one or more non-contact probes.

13. The method of claim 12, wherein analyzing the measured charge comprises mapping a distribution of charge on the semiconductor wafer based on measurements made while causing the relative motion between the semiconductor wafer and the probe assembly.

14. The method of claim 13, further comprising identifying a charging pattern attributable to the processing tool based on the mapped charge distribution.

15. The method of claim 14, further comprising making adjustments to the processing tool or to a processing step based on the charging pattern.

16. The method of claim 9, wherein the probe assembly comprises multiple non-contact probes and a surface voltage readout for each probe in the probe assembly is calibrated using surface voltage data measured by each probe at one or more common positons relative to the semiconductor wafer.

17. The method of claim 1, wherein the semiconductor wafer comprises at least one patterned layer corresponding to integrated circuit structures during the processing.

18. The method of claim 1, wherein the charge monitoring module comprises a chamber housing the probe assembly that provides environmental separation of the probe assembly from a processing environment associated with the processing station.
